(19) United States
(12) Patent Application Publication
(10) Pub. No.: US 2025/0048654 A1
(43) Pub. Date: Feb. 6, 2025

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventor: Nam Jae LEE, Gyeonggi-do (KR)

(21) Appl. No.: 18/499,209

(22) Filed: Nov. 1, 2023

(30) Foreign Application Priority Data
Aug. 3, 2023 (KR) 10-2023-0101390

(51) Int. Cl. H10B 80/00; H01L 23/00; H01L 25/00; H01L 25/065; H01L 25/18; H10B 41/10; H10B 41/27; H10B 43/10; H10B 43/27

(52) U.S. Cl. CPC H10B 80/00; H01L 24/08; H01L 24/80; H01L 25/0657; H01L 25/18; H01L 25/50; H10B 41/10; H10B 41/27; H10B 43/10; H10B 43/27; H01L 2224/08145; H01L 2224/80895; H01L 2224/80896; H01L 2924/1431; H01L 2924/14511

(57) ABSTRACT

A semiconductor device may include a gate structure including gate lines extending in a first direction; a first source pattern located on the gate structure; second source patterns located on the first source pattern and extending in a second direction intersecting the first direction; and channel structures extending through the gate structure and protruding into the first source pattern.

### CROSS-REFERENCE TO RELATED APPLICATION

This application claims priority under 35 U.S.C. § 119 to Korean Patent Application No. 10-2023-0101390 filed on Aug. 3, 2023, which is incorporated herein by reference in its entirety.

### BACKGROUND

### 1. Technical Field

Various embodiments of the present disclosure relate to an electronic device and a manufacturing method of the electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device stacking memory cells in a three-dimensional array over a substrate has been proposed. Furthermore, for improving the operational reliability of such semiconductor device, various structures and manufacturing methods continue to be developed.

### SUMMARY

In an embodiment of the present disclosure, a semiconductor device may include: a gate structure including gate lines extending in a first direction; a first source pattern located on the gate structure; second source patterns spaced apart from each other along the first direction, the second source patterns located on the first source pattern and extending in a second direction intersecting the first direction; and channel structures spaced apart from each other along the first direction, each channel structure extending through the gate structure and protruding into the first source pattern.

In an embodiment of the present disclosure, a semiconductor device may include: a gate structure including a cell region and a contact region and including gate lines extending in a first direction; a first source pattern located on the cell region of the gate structure; second source patterns located on the first source pattern and extending in a second direction intersecting the first direction; first insulating layers respectively located between the second source patterns; and a second insulating layer located on the contact region.

In an embodiment of the present disclosure, a manufacturing method of a semiconductor device may include: forming a stack on a substrate, the stack including second material layers extending in a first direction; forming channel structures extending into the substrate through the stack; exposing the channel structures by removing the substrate; forming a first source layer on the exposed channel structures; and forming second source patterns on the first source layer, the second source patterns extending in a second direction intersecting the first direction.

In an embodiment of the present disclosure, a manufacturing method of a semiconductor device may include: forming a gate structure including a cell region and a contact region and including gate lines extending in a first direction; forming contact plugs in the contact region, the contact plugs being connected to the gate lines, respectively; forming a first source layer on a back surface of the gate structure, the first source layer being located on the cell region and the contact region; forming second source patterns in the cell region of the gate structure, the second source patterns being located on the first source layer and extending in a second direction intersecting the first direction; and forming first insulating layers between the second source patterns.

These and other features and advantages of the present disclosure will become better understood from the following figures and detailed description of embodiments of the present disclosure.

### BRIEF DESCRIPTION OF THE DRAWINGS

FIGS. 1A to 1C are simplified diagrams illustrating a semiconductor device in accordance with an embodiment of the present disclosure.

FIGS. 2A to 2C are simplified diagrams illustrating a semiconductor device in accordance with an embodiment of the present disclosure.

FIG. 3 is a diagram for describing a semiconductor device in accordance with an embodiment of the present disclosure.

FIGS. 4 to 10B are simplified diagrams illustrating a manufacturing method of a semiconductor device in accordance with an embodiment of the present disclosure.

### DETAILED DESCRIPTION

Various embodiments of the present disclosure are directed to a semiconductor device having a stable structure and improved characteristics and a manufacturing method of the semiconductor device.

According to the present technology, it is possible to a semiconductor device having a stable structure and improved reliability.

Hereafter, embodiments in accordance with the technical spirit of the present disclosure will be described with reference to the accompanying drawings.

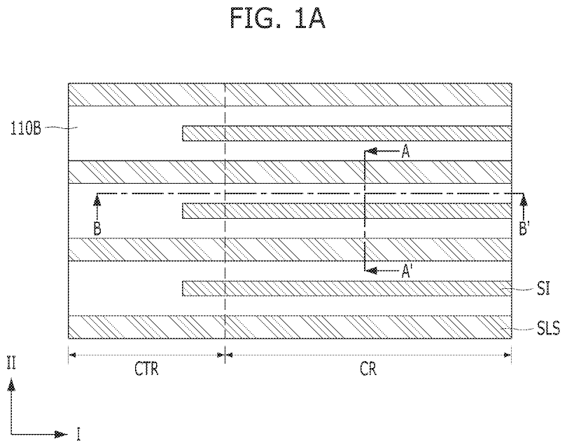

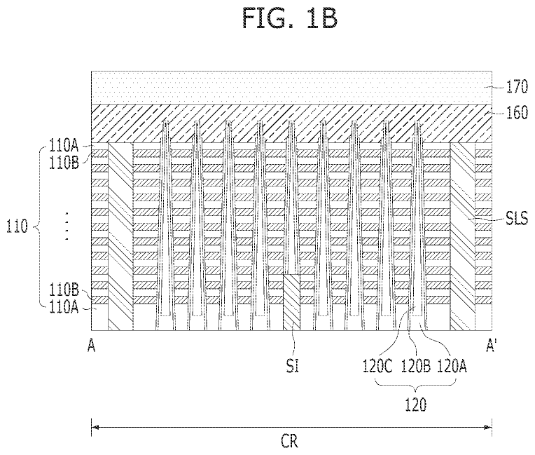

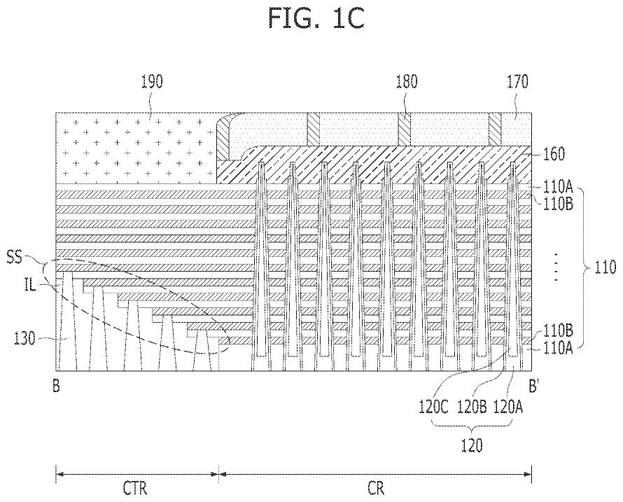

FIGS. 1A to 1C are simplified diagrams illustrating a semiconductor device in accordance with an embodiment of the present disclosure. FIG. 1A is a plan view, FIG. 1B is a cross-sectional view taken along line A-A′ of FIG. 1A, and FIG. 1C is a cross-sectional view taken along line B-B′ of FIG. 1A.

For reference, FIG. 1A is a schematic plan view for describing relative locations between structures included in the semiconductor device, and some structures of FIGS. 1B and 1C may be omitted or some regions of FIGS. 1B and 1C may be enlarged or reduced in FIG. 1A. Referring to FIGS. 1A to 1C, the semiconductor device may include a gate structure 110, channel structures 120, and a first source pattern 160 or second source patterns 170, or a combination thereof. The semiconductor device may further include contact plugs 130, first insulating layers 180, second insulating layers 190, interlayer insulating layers IL, and separation insulating layers SI or slit structures SLS, or a combination thereof.

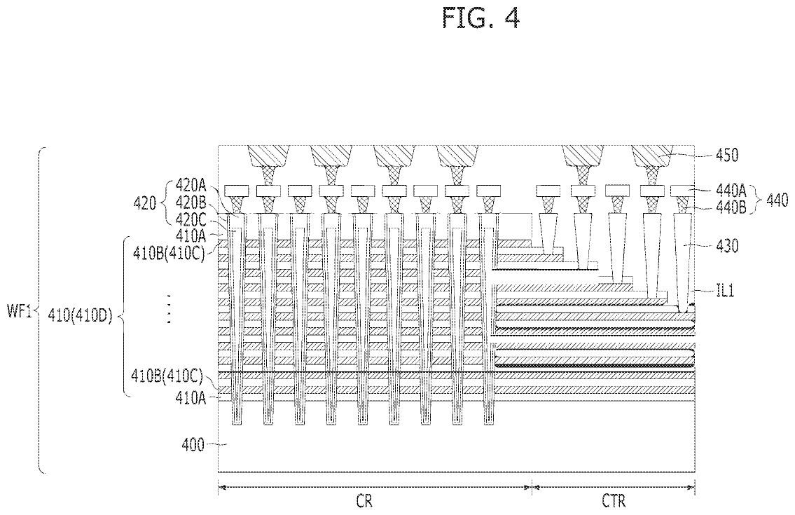

The gate structure 110 may include insulating layers 110A and gate lines 110B that are alternately stacked. The gate lines 110B may extend in a first direction I. The gate structure 110 may include a cell region CR and a contact region CTR adjacent to each other in the first direction I. The gate structure 110 may include a step structure shown in FIG. 4. Each of the gate lines 110B may be exposed by the step structure. For reference, although not illustrated in FIGS. 1A to 1C, the gate structure 110 might not include a step structure. The gate lines 110B may be source select lines, drain select lines, word lines, or bit lines. The insulating layers 110A may each include an insulating material such as oxide. The gate lines 110B may each include a conductive material such as tungsten, molybdenum, or polysilicon.

The channel structures 120 may be located in the gate structure 110. The channel structures 120 may be located in the cell region CR of the gate structure 110. Each of the channel structures 120 may include a channel layer 120A or a memory layer 120B, or a combination thereof. Each of the channel structures 120 may further include an insulating core 120C. The memory layer 120B may surround the channel layer 120A. The insulating core 120C may be located in the channel layer 120A.

The contact plugs 130 may be respectively connected to the gate lines 110B of the gate structure 110 through the interlayer insulating layer IL. For example, the contact plugs 130 may be respectively connected to the gate lines 110B in the contact region CTR. For reference, when the gate structure 110 does not include the step structure, the contact plugs 130 may extend through the gate structure 110 and be connected to the gate lines 110B, respectively. The contact plugs 130 may each include a conductive material such as tungsten.

The first source pattern 160 may be located on the gate structure 110. For example, the first source pattern 160 may be located on the cell region CR. The first source pattern 160 may be connected to the channel structures 120. For example, the first source pattern 160 may be connected to the channel structures 120 protruding into the first source pattern 160 through the gate structure 110. Here, the channel layer 120A of each of the channel structures 120 and the first source pattern 160 may be connected to each other. The first source pattern 160 may include polysilicon.

The second source patterns 170 may be located on the first source pattern 160. The second source patterns 170 may be located on the cell region CR of the gate structure 110. The second source patterns 170 may each include a material having a lower specific resistance than the first source pattern 160. For example, the second source patterns 170 may each include metal. The second source patterns 170 may each include tungsten.

The second source patterns 170 may each extend in a second direction II intersecting the first direction I. For example, the second source patterns 170 may extend in the second direction II intersecting the gate lines 110B extending in the first direction I. As the second source patterns 170 extend in a direction intersecting the gate lines 110B, stress may be generated in different directions in the second source patterns 170 and the gate lines 110B. For example, stress may be generated in the first direction I in the gate lines 110B, and stress may be generated in the second direction II intersecting the first direction I in the second source patterns 170. Accordingly, warpage of the semiconductor device may be reduced by the gate lines 110B and the second source patterns 170 intersecting each other in different directions.

The first insulating layers 180 may be located between the second source patterns 170. The first insulating layers 180 may be located on the cell region CR of the gate structure 110. The first insulating layers 180 may extend in the second direction II intersecting the gate lines 110B extending in the first direction I. The first insulating layers 180 may each include an insulating material such as oxide.

The second insulating layer 190 may be located on the gate structure 110. For example, the second insulating layer 190 may be located on the contact region CTR of the gate structure 110. A level of a lower surface of the second insulating layer 190 may be substantially the same as or different from that of a lower surface of each of the first insulating layers 180. For example, the level of the lower surface of the second insulating layer 190 may be located below the level of the lower surface of each of the first insulating layers 180. This is because the source patterns 160 and 170 are not located on the contact region CTR. The second insulating layer 190 may extend in the second direction II intersecting the gate lines 110B extending in the first direction I. The second insulating layer 190 may include an insulating material such as oxide.

The separation insulating layers SI may be located in the gate structure 110. For example, the separation insulating layers SI may be located in the cell region CR. The separation insulating layers SI may each extend in the first direction I. For example, the separation insulating layers SI may each extend in the first direction I through the cell region CR and extend to the contact region CTR. The separation insulating layer SI may be located between the channel structures 120. The separation insulating layer SI may partially penetrate through the channel structure 120. For example, the separation insulating layer SI may insulate some of the gate lines 110B by partially penetrating through the channel structure 120. Here, the insulated gate lines 110B may be drain select lines. The channel structure 120 through which the separation insulating layer SI partially penetrates may be used as a real channel structure or used as a dummy channel structure. The separation insulating layer SI may include an insulating material such as oxide.

The slit structures SLS may be located in the gate structure 110. For example, the slit structures SLS may be located in the cell region CR. The slit structures SLS may each extend in the first direction I. For example, the slit structures SLS may each extend in the first direction I through the cell region CR and extend to the contact region CTR. The separation insulating layer SI may be located between the slit structures SLS. The slit structures SLS may be formed in slits used as passages for replacing sacrificial layers (not illustrated) with the gate lines 110B. The slit structures SLS may each include an insulating material such as oxide or include a source contact structure.

According to the structure described above, the gate lines 110B may each extend in the first direction I. The second source patterns 170 may each extend in the second direction II intersecting the first direction I. Accordingly, the warpage of the semiconductor device may be reduced by the second source patterns 170 formed in the direction intersecting the gate lines 110B.

In addition, the first source pattern 160 including polysilicon and the second source patterns 170 including a material having a lower specific resistance than the first source pattern 160 may be located on the cell region CR of the gate structure 110. That is, a source structure including the first and second source patterns 160 and 170 configured as multiple layers may be formed. Accordingly, resistance of the source structure may be lowered as compared with a case where the source structure is formed as a polysilicon single layer, and source bouncing may be reduced. A threshold voltage distribution of memory cells may be reduced, a program speed may be improved, and operating characteristics may be improved. Because the resistance of the source structure is reduced, a layout of upper wiring lines may be changed, and wiring lines conventionally connected to the source structure may be used as data wiring lines or power wiring lines.

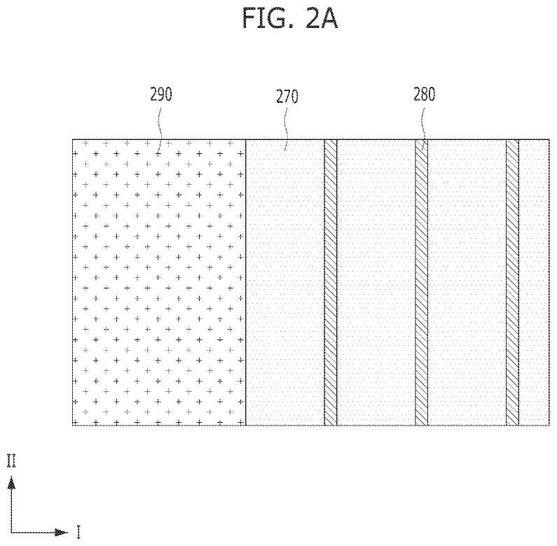

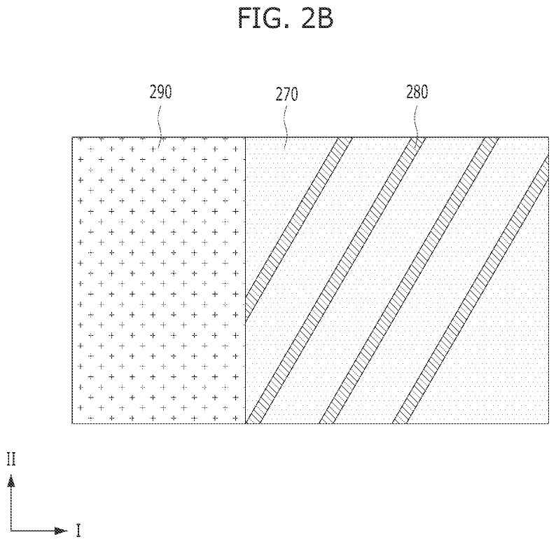

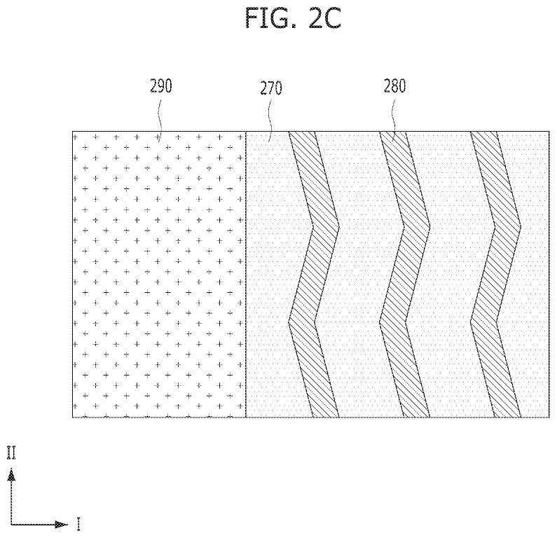

FIGS. 2A to 2C are simplified diagrams illustrating a semiconductor device in accordance with an embodiment of the present disclosure. FIGS. 2A to 2C are plan views. Hereinafter, any content overlapping with previously described content may be omitted.

Referring now to FIGS. 2A to 2C, second source patterns 270, first insulating layers 280, and a second insulating layer 290 may extend in the second direction II. Referring to FIG. 1A again, the gate lines 110B may extend in the first direction I. Namely, the second source patterns 270, the first insulating layers 280, and the second insulating layer 290 may extend in the second direction II intersecting the gate lines 110B extending in the first direction I. Accordingly, stress generated in the first direction I and stress generated in the second direction II may offset each other, such that warpage of the semiconductor device may be reduced.

Shapes, thicknesses, widths, or the like, of the second source patterns 270 may be various. Referring to FIG. 2A, each of the second source patterns 270 may have a straight line shape in which it extends in the second direction II intersecting the first direction I. The first insulating layer 280 located between the second source patterns 270 may also have a straight line shape.

Referring to FIG. 2B, each of the second source patterns 270 may extend in an oblique line direction intersecting the first direction I at an acute angle. The first insulating layer 280 located between the second source patterns 270 may also have a shape in which it extends in the oblique line direction.

Referring to FIG. 2C, each of the second source patterns 270 may extend in a zigzag shape. Alternatively, each of the second source patterns 270 may extend in a wavy shape. The first insulating layer 280 located between the second source patterns 270 may also extend in a wavy shape.

According to the structure described above, the second source patterns 270 and the first insulating layers 280 may have various shapes. For example, each of the second source patterns 270 may extend in a straight line shape, an oblique line shape, or a zigzag shape. The first insulating layer 280 located between the second source patterns 270 may also extend in a straight line shape, an oblique line shape, or a zigzag shape. However, the shapes of the second source patterns 270 and the first insulating layers 280 are not limited thereto. The second source patterns 270 and the first insulating layers 280 may have any shape as long as they may extend in the second direction II to reduce stress of the gate lines 110B extending in the first direction I.

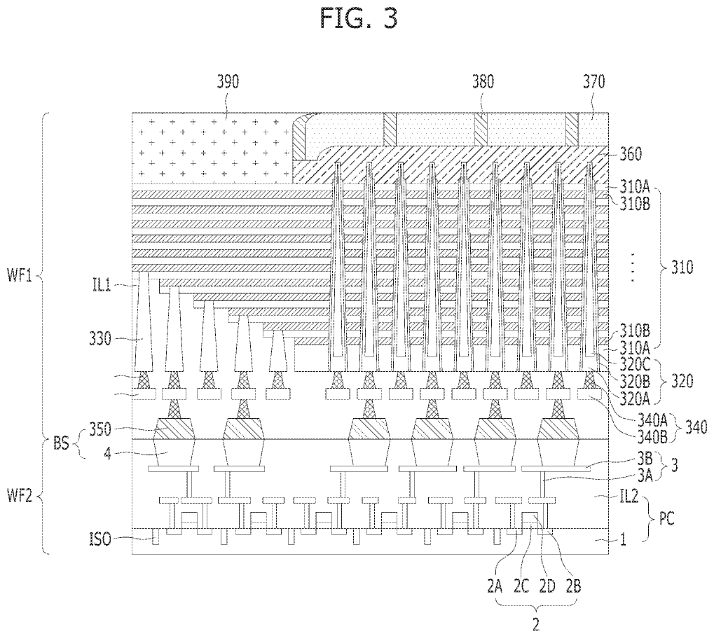

FIG. 3 is a diagram for describing a semiconductor device in accordance with an embodiment of the present disclosure. Hereinafter, any content overlapping with previously described content may be omitted.

Referring to FIG. 3, the semiconductor device may include a first structure WF1 or a second structure WF2, or a combination thereof. The first structure WF1 may refer to a first structure that does not include a substrate and includes a gate structure 310, channel structures 320, and a first source pattern 360 or second source patterns 370, or a combination thereof. The first structure WF1 may further include contact plugs 330, first insulating layers 380, a second insulating layer 390, an interlayer insulating layer IL1, and a first interconnection structure 340 or first bonding pads 350, or a combination thereof.

The first interconnection structure 340 may be located below the gate structure 110. The first interconnection structure 340 may include first contact vias 340A or first wiring lines 340B, or a combination thereof. The first interconnection structure 340 may be connected to the channel structures 320 or the contact plugs 330. For example, the first contact vias 340A may be connected to the channel structures 320 or the contact plugs 330, respectively. Each of the first wiring lines 340B may be connected to the first contact via 340A. The first contact vias 340A or the first wiring lines 340B may each include a conductive material such as tungsten.

The first bonding pads 350 may be located below the first interconnection structure 340. Each of the first bonding pads 350 may be connected to the first interconnection structure 340. For example, each of the first bonding pads 350 may be connected to at least one of the first wiring lines 340B. The channel structures 320 and the contact plugs 330 may be electrically connected to the second structure WF2 through the first interconnection structure 340 and the first bonding pads 350.

The second structure WF2 may include a substrate 1, a peripheral circuit PC, and a second interconnection structure 3 or second bonding pads 4, or a combination thereof. The second structure WF2 may further include an interlayer insulating layer IL2 or an element isolation layer ISO, or a combination thereof.

The peripheral circuit PC may be located on the substrate 1, and the element isolation layer ISO may be located in the substrate 1. An active region may be defined by the element isolation layer ISO. The peripheral circuit PC may include transistors 2, capacitors, resistors, and the like. For example, the transistor 2 may include a first junction 2A, a second junction 2B, a gate insulating layer 2C, or a gate electrode 2D. The gate insulating layer 2C may be located between the gate electrode 2D and the substrate 1. The gate insulating layer 2C and the element isolation layer ISO may each include an insulating material such as oxide or nitride.

The second interconnection structure 3 may include second contact vias 3A or second wiring lines 3B, or a combination thereof. The interlayer insulating layer IL2 may be located on the substrate 1. The second interconnection structure 3 may be located in the interlayer insulating layer IL2. The second interconnection structure 3 may be connected to the peripheral circuit PC. Each of the second contact vias 3A may connect the junctions 2A and 2B of the transistor 2 to the second wiring line 3B or may connect the second wiring lines 3B to each other. Each of the second wiring lines 3B may be connected to the second contact via 3A, connect the second contact vias 3A to each other, or connect the second bonding pads 4 to the second contact via 3A. The second contact vias 3A or the second wiring lines 3B may each include a conductive material such as tungsten.

The second bonding pads 4 may be located on the second interconnection structure 3. Each of the second bonding pads 4 may be connected to the second interconnection structure 3. For example, each of the second bonding pads 4 may be connected to at least one of the second wiring lines 3B. The peripheral circuit PC may be electrically connected to the first structure WF1 through the second interconnection structure 3 and the second bonding pads 4.

A bonding structure BS electrically connecting the first interconnection structure 340 and the second interconnection structure 3 to each other may be defined. The bonding structure BS may include the first bonding pads 350 and the second bonding pads 4. The first structure WF1 and the second structure WF2 may be bonded to each other. For example, the first structure WF1 and the second structure WF2 may be bonded to each other through the bonding structure BS. Namely, the first bonding pads 350 of the first structure WF1 and the second bonding pads 4 of the second structure WF2 may be bonded to each other. Accordingly, the first structure WF1 may be located on the second structure WF2. Here, in a state in which the first structure WF1 is rotated, an upper portion of the second structure WF2 and an upper portion of the first structure WF1 may be bonded to each other.

For reference, here, an upper portion and a lower portion are relative concepts for convenience of description. The source patterns 360 and 370 may be located below the gate structure 310. Alternatively, the second structure WF2 may be located on the first structure WF1. Accordingly, in a state in which the second structure WF2 is rotated, an upper portion of the second structure WF2 and an upper portion of the first structure WF1 may be bonded to each other.

According to the structure described above, by separately forming the first structure WF1 including a cell array and the second structure WF2 including the peripheral circuit PC, it is possible to increase the degree of integration of a memory of the semiconductor device.

In addition, warpage of the first structure WF1 may be reduced by the second source patterns 370 extending in the second direction II intersecting gate lines 310B extending in the first direction I in the first structure WF1. Accordingly, stress at a bonding interface between the first structure WF1 and the second structure WF2 may be reduced, and a delamination phenomenon at the bonding interface may be reduced.

FIGS. 4 to 10B are simplified diagrams illustrating a manufacturing method of a semiconductor device in accordance with an embodiment of the present disclosure. Hereinafter, any content overlapping with previously described content may be omitted.

Referring to FIG. 4, a first wafer WF1 may be formed. First, a stack 410D may be formed on a substrate 400. The stack 410D may include first material layers 410A and second material layers 410C that are alternately stacked. The first material layers 410A may each include an insulating material such as oxide. The second material layers 410C may each include a sacrificial material such as nitride. Alternatively, the first material layers 410A may each include an insulating material such as oxide. The second material layers 410C may each include a conductive material such as polysilicon. Subsequently, channel structures 420 extending into the stack 410D may be formed. Each of the channel structures 420 may include a channel layer 420A and a memory layer 420B surrounding the channel layer 420A or an insulating core 420C located in the channel layer 420A, or a combination thereof.

A step structure may be formed in the stack 410D. Each of the second material layers 410C of the stack 410D may be exposed through the step structure. After the step structure is formed, an interlayer insulating layer IL1 may be formed on the stack 410D. For reference, a process of forming the step structure in the stack 410D may be omitted. Contact plugs 430 respectively connected to the second material layers 410C of the stack 410D may be formed. For example, the contact plugs 430 extending through the interlayer insulating layer IL1 and respectively connected to the second material layers 410C may be formed. For reference, when the stack 410D does not include the step structure, the contact plugs 430 extending through the stack 410D and respectively connected to the second material layers 410C may be formed.

A gate structure 410 may be formed by replacing the second material layers 410C of the stack 410D with gate lines 410B. For example, the sacrificial material of the second material layers 410C may be replaced with a conductive material through a slit (not illustrated). Here, the gate lines 410B may each include a conductive material such as tungsten, molybdenum, or polysilicon. The gate lines 410B may be select lines, word lines, or bit lines. The gate structure 410 may include a cell region CR and a contact region CTR. The channel structures 420 may be formed in the cell region CR of the gate structure 410. The contact plugs 430 may be formed in the contact region CTR of the gate structure 410. Accordingly, the contact plugs 430 may be respectively connected to the gate lines 410B of the gate structure 410 in the contact region CTR.

For reference, when the second material layers 410C each include a conductive material, a process of replacing the second material layers 410C with the gate lines 410B may be omitted. In this case, the second material layers 410C may be used as the gate lines 410B. The stack 410D may be used as the gate structure 410.

Subsequently, a first interconnection structure 440 may be formed on the gate structure 410. For example, the first interconnection structure 440 connected to the channel structures 420 and the contact plugs 430 may be formed. The first interconnection structure 440 may include first contact vias 440A and first wiring lines 440B. Each of the first contact vias 440A may be connected to at least one of the channel structures 420. Alternatively, each of the contact vias 440A may be connected to at least one of the contact plugs 430. The first wiring lines 440B may be connected to the first contact vias 440A, respectively, or may connect the first contact vias 440A to each other.

Subsequently, first bonding pads 450 may be formed on the first interconnection structure 440. At least one of the first contact vias 440A may be connected to at least one of the first bonding pads 450. The first bonding pads 450 may be electrically connected to the channel structures 420 and the contact plugs 430 through the first interconnection structure 440.

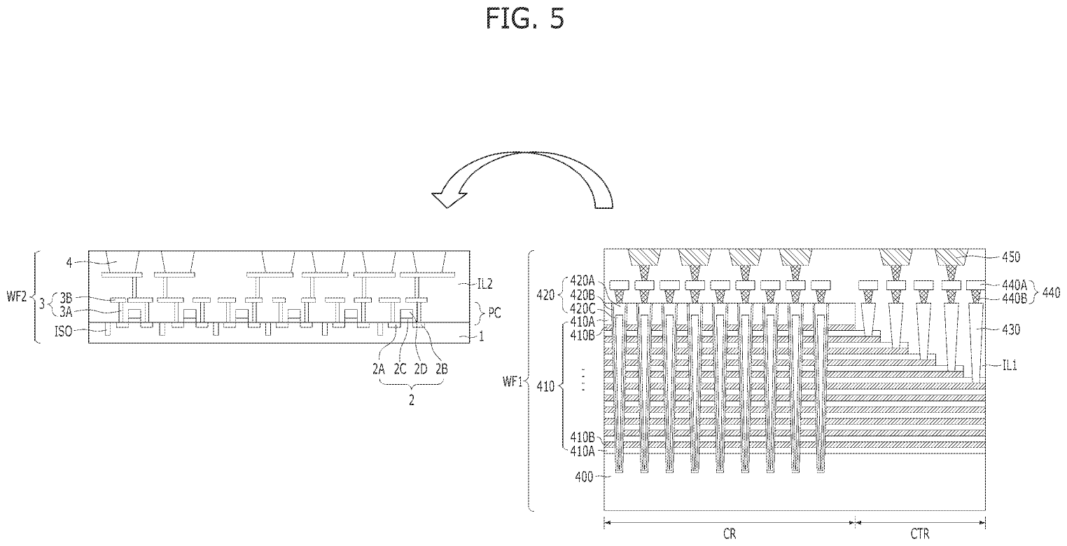

Referring to FIG. 5, a second wafer WF2 may be formed. First, a peripheral circuit PC may be formed on a substrate 1. An element isolation layer ISO may be located in the substrate 1, and an active region may be defined by the element isolation layer ISO. The peripheral circuit PC may include transistors 2, resistors, capacitors, and the like. The transistors 2 may include at least one of a first junction 2A, a second junction 2B, a gate insulating layer 2C, and a gate electrode 2D. The gate insulating layer 2C may be formed between the substrate 1 and the gate electrode 2D. The gate insulating layer 2C and the element isolation layer ISO may each include an insulating material such as oxide or nitride. An interlayer insulating layer IL2 may be formed on the substrate 1, and a second interconnection structure 3 may be formed in the interlayer insulating layer IL2.

Second bonding pads 4 may be formed on the second interconnection structure 3. The second interconnection structure 3 may include second contact vias 3A and second wiring lines 3B. The second contact vias 3A may connect the peripheral circuit PC and the second wiring lines 3B to each other. The second wiring line 3B may connect the second contact vias 3A to each other or connect the second contact via 3A to the second bonding pad 4. The second bonding pads 4 may be electrically connected to the peripheral circuit PC through the second interconnection structure 3. Consequently, the second wafer WF2 including the peripheral circuit PC may be formed.

Subsequently, the second wafer WF2 and the first wafer WF1 may be bonded to each other. An upper surface of the second wafer WF2 and an upper surface of the first wafer WF1 may be bonded to each other. For example, the first bonding pads 450 of the first wafer WF1 and the second bonding pads 4 of the second wafer WF2 may be connected to each other. Accordingly, the peripheral circuit PC of the second wafer WF2 may be electrically connected to the channel structures 420 and the contact plugs 430 through the bonding pads 4 and 450. By separately forming the first wafer WF1 including a cell array and the second wafer WF2 including the peripheral circuit PC, it is possible to improve the degree of integration of a memory of the semiconductor device.

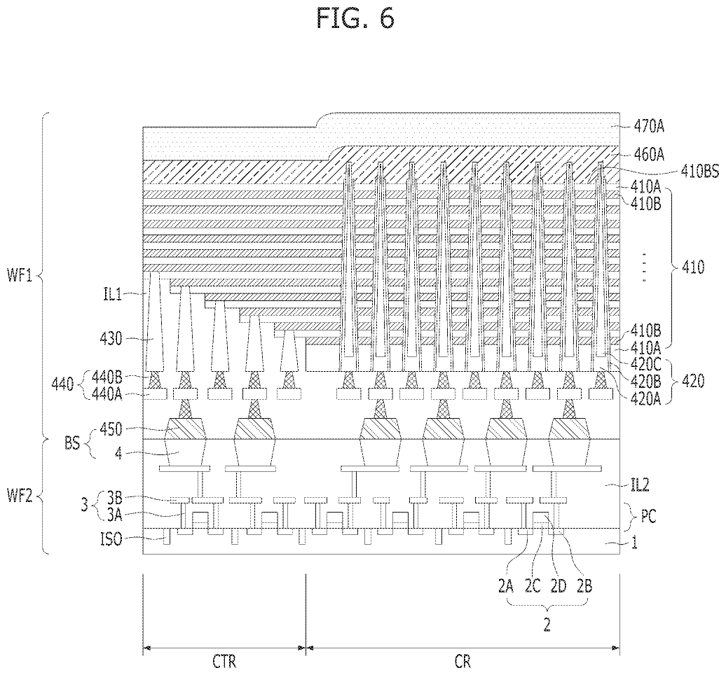

Referring to FIG. 6, after the first and second wafers WF1 and WF2 are bonded to each other, the substrate 400 may be removed. The channel structures 420 may be exposed by removing the substrate 400. Subsequently, the channel layer 420A of each of the channel structures 420 may be exposed. For example, the channel layer 420A may be exposed by etching the memory layer 420B exposed by removing the substrate 400.

Subsequently, a first source layer 460A may be formed on the exposed channel structures 420. The first source layer 460A may be formed on a back surface 410BS of the gate structure 410. For example, the first source layer 460A may be formed on the cell region CR and the contact region CTR of the gate structure 410, on the back surface 410BS of the gate structure 410. The first source layer 460A may include polysilicon.

Subsequently, a second source layer 470A may be formed on the first source layer 460A. The second source layer 470A may include a material having a lower specific resistance than the first source layer 460A. For example, the second source layer 470A may include tungsten. A multilayer source structure is formed by forming the second source layer 460A including the material (e.g., tungsten) having the lower specific resistance than the first source layer 460A including polysilicon on the first source layer 460A, and accordingly, resistance of the source structure may be lowered. Accordingly, source bouncing of the source structure may be reduced, and characteristics of a memory cell may be improved.

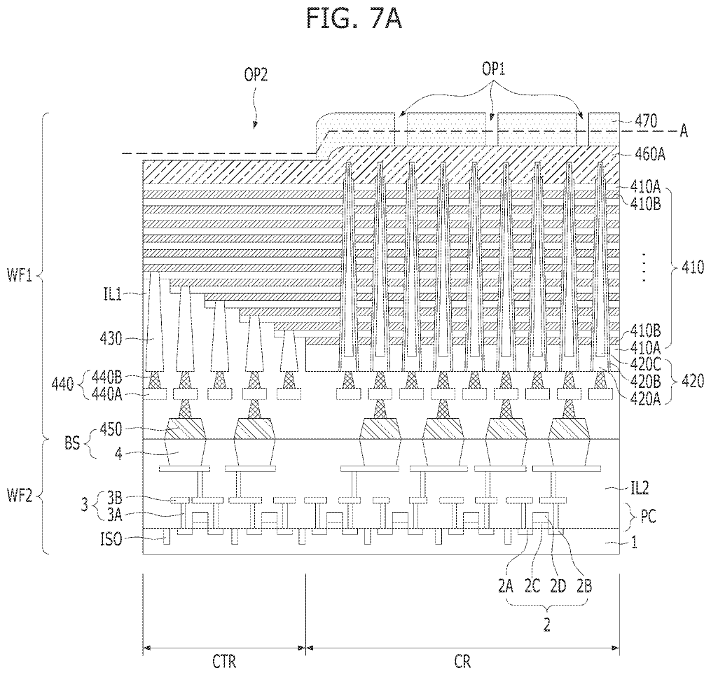

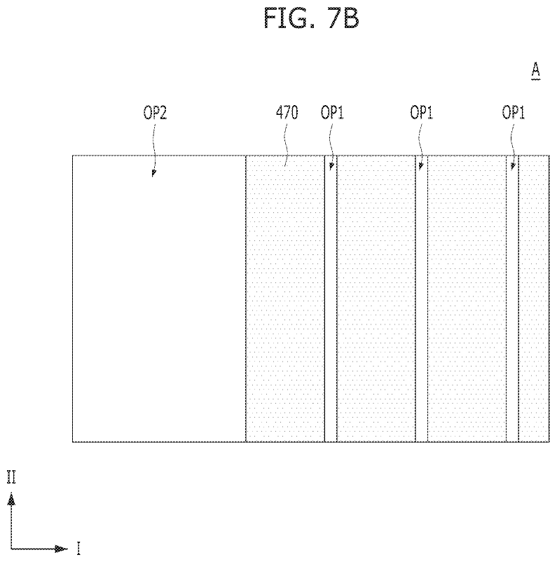

Referring to FIGS. 7A and 7B, second source patterns 470 may be formed. For example, the second source patterns 470 may be formed on the cell region CR of the gate structure 410. First, a mask pattern may be formed by forming a mask layer (not illustrated) on the second source layer 470A and then patterning the mask layers (not illustrated) to be spaced apart from each other in the first direction I. For example, the mask pattern exposing a portion corresponding to a portion of the contact region CTR of the gate structure 410 and a portion corresponding to a portion of the cell region CR of the gate structure 410 may be formed on the second source layer 470A. Subsequently, the second source layer 470A may be etched using the mask pattern as an etching barrier. Through this, first openings OP1 may be formed. Accordingly, the first openings OP1 extending in the second direction II intersecting the first direction I and exposing the first source layer 460A may be formed in the second source layer 470A. Here, the first openings OP1 may be formed on the cell region CR. The second source layer 470A may be separated into the second source patterns 470 by the first openings OP1.

Shapes, widths, thicknesses, or the like, of the first openings OP1 for forming the second source patterns 470 may be various. Referring to FIG. 7B, each of the first openings OP1 may have a straight line shape in which it extends in the second direction II intersecting the first direction I. However, the present disclosure is not limited thereto, and each of the first openings OP1 may have a shape extending in an oblique line direction intersecting the first direction I at an acute angle, a zigzag shape, or the like. Accordingly, each of the second source patterns 470 may also have a straight line shape, an oblique line shape, a zigzag shape, or the like.

When the first openings OP1 are formed on the cell region CR, a second opening OP2 exposing the first source layer 460A may be formed on the contact region CTR. The second opening OP2 exposing the first source layer 460A may be formed by etching a portion of the second source layer 470A formed on the contact region CTR.

The gate lines 410B may each extend in the first direction I. The second source patterns 470 may each extend in the second direction II intersecting the first direction I. The gate lines 410B may generate stress in the first direction I. The second source patterns 470 may generate stress in the second direction II. Accordingly, the stresses are generated in different directions in the gate lines 410B and the second source patterns 470 and may thus offset each other. Therefore, warpage of the semiconductor device may be reduced.

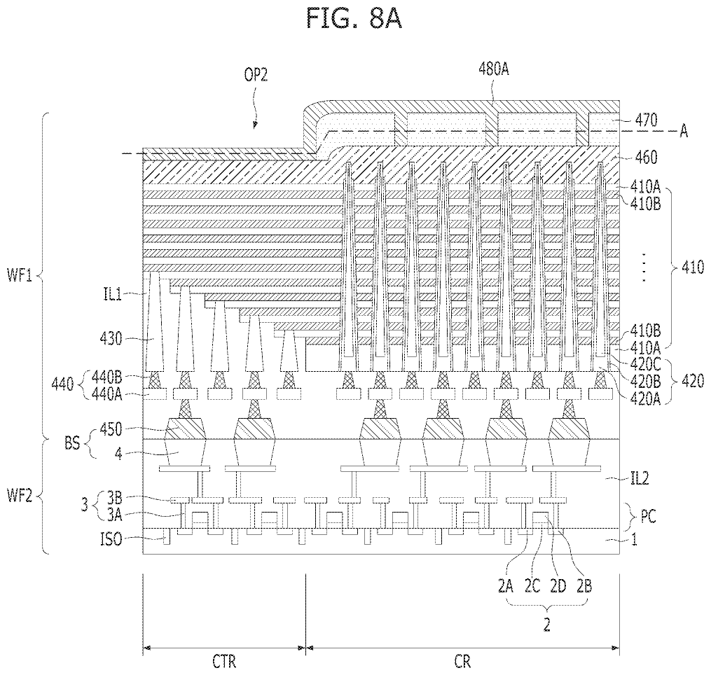

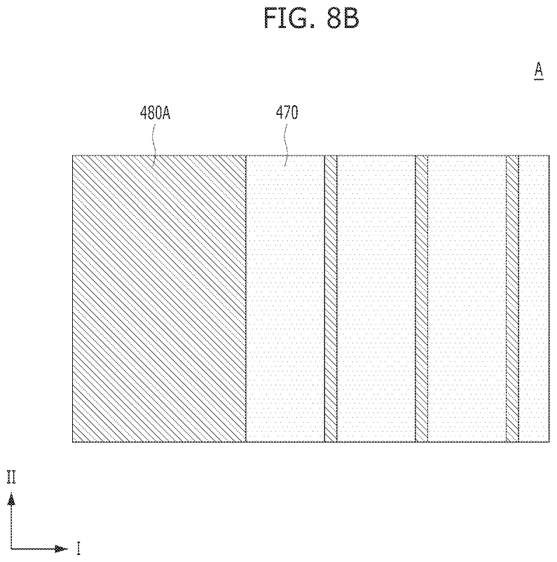

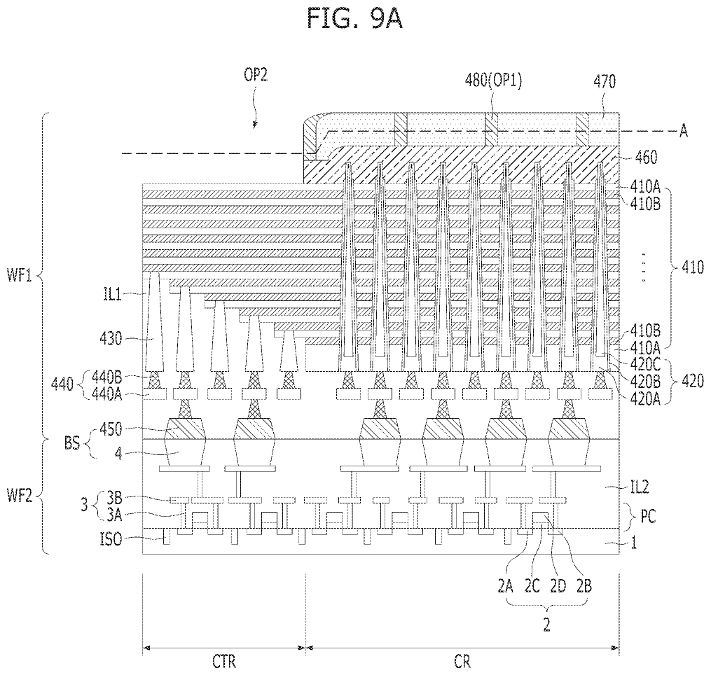

Referring to FIGS. 8A and 8B, a first preliminary insulating layer 480A may be formed. The first preliminary insulating layer 480A may be formed on the first openings OP1 and the second opening OP2. The first preliminary insulating layer 480A may be formed to partially fill the second opening OP2 while being formed to fill the first openings OP1. The first preliminary insulating layer 480A may include an insulating material such as oxide.

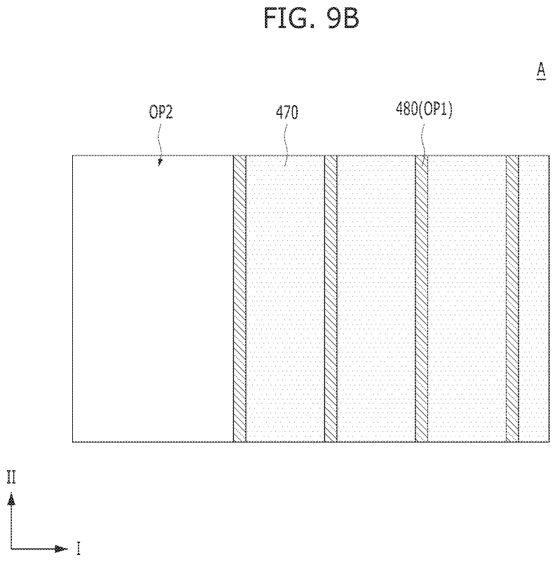

Referring to FIGS. 9A and 9B, first insulating layers 480 may be formed. The first preliminary insulating layer 480A may be etched so that the second source patterns 470 are exposed. Consequently, the first insulating layers 480 may be formed in the first openings OP1, respectively. Namely, the first insulating layers 480 may extend along the first source layer 460A exposed by removing the second source layer 470A. The first insulating layers 480 may be formed between the second source patterns 470. Here, the first preliminary insulating layer 480A formed on the contact region CTR of the gate structure 410 may partially remain.

Subsequently, the contact region CTR of the gate structure 410 may be exposed. For example, the contact region CTR of the gate structure 410 may be exposed by etching a portion of the first source layer 460A formed on the contact region CTR through the second opening OP2. Here, the partially remaining first preliminary insulating layer 480A may also be etched and removed. Consequently, a first source pattern 460 located on the cell region CR may be formed by etching the portion of the first source layer 460A formed on the contact region CTR. In this case, the back surface 410BS of the contact region CTR of the gate structure 410 may be exposed.

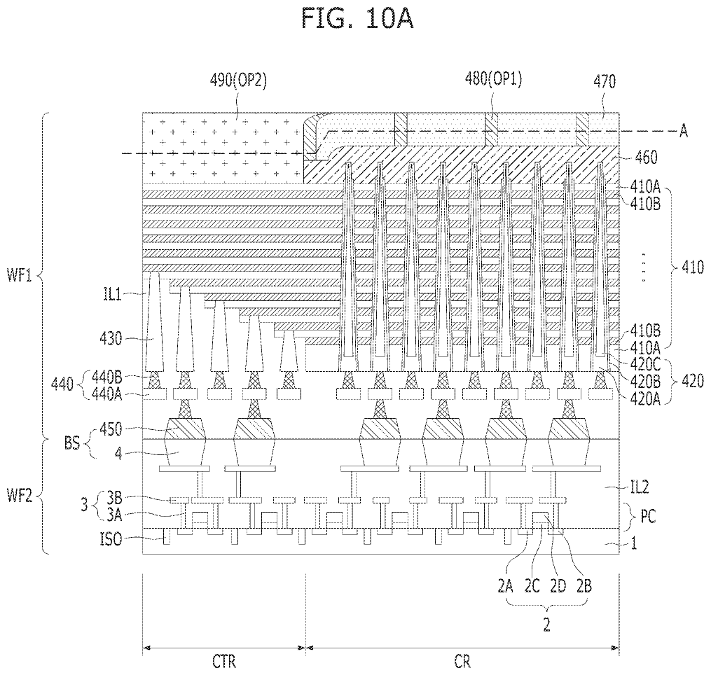

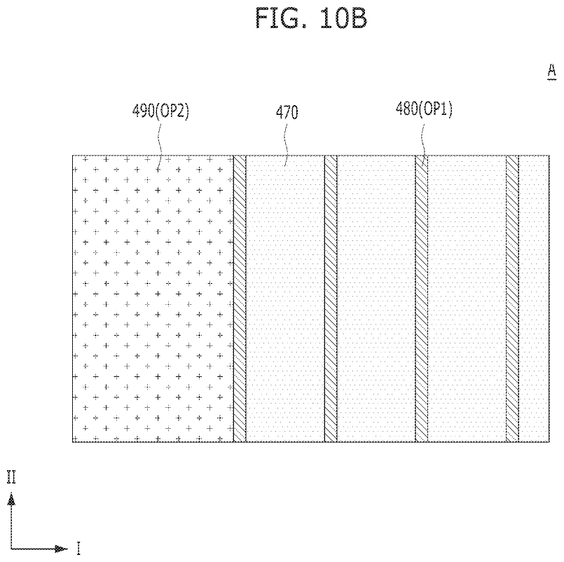

Referring to FIGS. 10A and 10B, a second insulating layer 490 may be formed on the contact region CTR of the gate structure 410. For example, the second insulating layer 490 may be formed in the second opening OP2. First, a second preliminary insulating layer (not illustrated) may be formed in the second opening OP2. Here, the second preliminary insulating layer (not illustrated) may also be formed on the cell region CR. Subsequently, the second insulating layer 490 may be formed in the second opening OP2 by etching the second preliminary insulating layer (not illustrated) so that the second source patterns 470 are exposed. Consequently, the second insulating layer 490 located on the contact region CTR may be formed on the back surface 410BS of the gate structure 410.

Here, a level of a lower surface of the second insulating layer 490 may be substantially the same as or different from that of a lower surface of each of the first insulating layers 480. For example, the level of the lower surface of the second insulating layer 490 may be formed below the level of the lower surface of each of the first insulating layers 480. This is because the second insulating layer 490 is formed after the source layers 460A and 470A which are formed on the contact region CTR are removed.

According to the manufacturing method described above, the gate lines 410B may be formed extending in the first direction I. Also, the source patterns 470 may be formed extending in the second direction II intersecting the first direction I. Accordingly, the stresses are generated in different directions in the gate lines 410B and the second source patterns 470 and may thus offset each other. Therefore, the warpage of the semiconductor device may be reduced.

In addition, after the first and second wafers WF1 and WF2 are bonded to each other, the substrate 400 of the first wafer WF1 may be removed. In a subsequent process, because the stresses may offset each other by forming the second source patterns 470 in a direction intersecting the gate lines 410B, stress at a bonding interface may also be reduced. Accordingly, it is possible to prevent, minimize, or reduce a delamination phenomenon at the bonding interface.

In addition, a multilayer source structure may be formed by forming the first source pattern 460 including polysilicon and the second source patterns 470 including a material having a lower specific resistance than the first source pattern 460. Accordingly, the resistance of the source structure may be reduced as compared with a case where the source structure is a single layer including polysilicon. Therefore, the source bouncing may be reduced. Also, the characteristics of the memory cell may be improved.

Although embodiments according to the technical idea of the present disclosure have been described above with reference to the accompanying drawings, this is only for describing the embodiments according to the concept of the present disclosure. The present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure. Furthermore, the embodiments may be combined to form additional embodiments.

What is claimed is:

1. A semiconductor device comprising:
a gate structure including gate lines extending in a first direction;
a first source pattern located on the gate structure;
second source patterns spaced apart from each other along the first direction, the second source patterns located on the first source pattern and extending in a second direction intersecting the first direction; and
channel structures spaced apart from each other along the first direction, each channel structure extending through the gate structure and protruding into the first source pattern.

2. The semiconductor device of claim 1, wherein the second source patterns include a material having a lower specific resistance than the first source pattern.

3. The semiconductor device of claim 1, wherein the first source pattern includes polysilicon, and the second source patterns include metal.

4. The semiconductor device of claim 1, wherein each of the second source patterns extends in an oblique line direction intersecting the first direction at an acute angle.

5. The semiconductor device of claim 1, wherein each of the second source patterns extends in a zigzag shape.

6. The semiconductor device of claim 1, wherein the gate structure includes a cell region and a contact region, and the channel structures are located in the cell region.

7. The semiconductor device of claim 6, further comprising contact plugs respectively connected to the gate lines in the contact region.

8. The semiconductor device of claim 6, wherein the first source pattern and the second source patterns are located on the cell region.

9. The semiconductor device of claim 1, further comprising:
a first interconnection structure located below the gate structure and connected to the channel structures;
a peripheral circuit;
a second interconnection structure connected to the peripheral circuit; and
a bonding structure electrically connecting the first interconnection structure and the second interconnection structure to each other.

10. The semiconductor device of claim 1, further comprising first insulating layers respectively located between the second source patterns and extending in the second direction.

11. The semiconductor device of claim 10, wherein the gate structure includes a cell region and a contact region, and the semiconductor device further comprising a second insulating layer located on the contact region.

12. The semiconductor device of claim 11, wherein a level of a lower surface of the second insulating layer is located below a level of a lower surface of each of the first insulating layers.

13. A semiconductor device comprising:
a gate structure including a cell region and a contact region and including gate lines extending in a first direction;
a first source pattern located on the cell region of the gate structure;
second source patterns located on the first source pattern and extending in a second direction intersecting the first direction;
first insulating layers respectively located between the second source patterns; and
a second insulating layer located on the contact region.

14. The semiconductor device of claim 13, wherein the second source patterns include a material having a lower specific resistance than the first source pattern.

15. The semiconductor device of claim 13, wherein each of the second source patterns extends in an oblique line direction intersecting the first direction at an acute angle or extends in a zigzag shape.

16. The semiconductor device of claim 13, wherein each of the first insulating layers extends in an oblique line direction intersecting the first direction at an acute angle or extends in a zigzag shape.

17. The semiconductor device of claim 13, further comprising:
channel structures located in the cell region; and
contact plugs respectively connected to the gate lines in the contact region.

18. The semiconductor device of claim 17, further comprising:
a first interconnection structure located below the gate structure and connected to the channel structures;
a peripheral circuit;
a second interconnection structure connected to the peripheral circuit; and
a bonding structure electrically connecting the first interconnection structure and the second interconnection structure to each other.
